(19) United States
(12) Patent Application Publication
(10) Pub. No.: US 2011/0012853 A1
(43) Pub. Date: Jan. 20, 2011

(54) TOUCH PANEL

(76) Inventors: Sean Chang, Taoyuan Hsien (TW); Chii-How Chang, Taoyuan Hsien (TW)

Correspondence Address: Muncy, Geissler, Olds & Lowe, PLLC, 4000 Legato Road, Suite 310, FAIRFAX, VA, 22033, US

(21) Appl. No.: 12/835,490

(22) Filed: Jul. 13, 2010

(30) Foreign Application Priority Data
Jul. 14, 2009 (TW) 098123709

(51) Int. Cl. G06F 3/041; H03K 17/96

(52) U.S. Cl. 345/173; 327/517

(57) ABSTRACT

A touch panel includes a sensing layer, which has a plurality of sensing lines extending along a first direction and arranged in a row along a second direction. Each of the sensing lines individually has a first end and a second end electrically connected to a detecting circuit respectively, and the detecting circuit computes a coordinate in the first direction of a touch position in accordance with voltage variation at the first and second ends of the sensing line.

### CROSS REFERENCE TO RELATED APPLICATIONS

This Non-provisional application claims priority under 35 U.S.C. §119(a) on Patent Application No(s). 098123709 filed in Taiwan, Republic of China on Jul. 14, 2009, the entire contents of which are hereby incorporated by reference.

### BACKGROUND OF THE INVENTION

1. Field of Invention

The present invention relates to a touch panel. More particularly, the present invention relates to a touch panel with a single sensing layer, which can increase the sensing refresh rate and improve the coordinate computing formulas.

2. Related Art

The touch-control technique has been widely used as the input means for various electronic devices nowadays. Users can read or transmit information just by pressing the touch panel with his/her finger or a touch stylus so that the traditional buttons, keyboard or mouse is not necessary.

In accordance with different sensing mechanisms, the touch panels can be classified into the resistance type, capacitance type, infrared ray type and ultrasonic wave type, etc. The latter two are to configure the emission sources of infrared rays or ultrasonic waves at two sides of the screen along the X- and Y-axis, respectively, and the receptors at the opposite sides. When the user touches the screen, the transmission of infrared ray or ultrasonic wave is interfered. Therefore, the device can compute and locate the coordinate of the interfered position to complete the touch input. In addition, the resistance-type touch panel includes two stacked conductive thin films such as the ITO (indium tin oxide) substrate. When the resistance-type touch panel is pressed, the top and bottom electrodes can be conducted. Then, the voltage variation of the panel can be detected by a controller so as to compute the touch position and thus complete the input. Regarding to the capacitance-type touch panel, it is composed of a transparent glass whose surface is plated with metallic oxide, and the four corners thereof provide voltages to form a uniform electric field on the surface of the glass. Accordingly, the input coordinate can be computed through detecting the capacitance variation caused by the electrostatic interaction between the user's finger and the electrical field.

Generally, the conventional sensing layer of the capacitance-type touch panel is a double layer structure. As shown in FIGS. 1A and 1B, touch devices, which are disclosed in U.S. Pat. Nos. 5,418,551 and 5,083,118, both have the double sensing layers. One of the double sensing layers is used to sense the coordinate in the X-axis, and the other is used to sense the coordinate in the Y-axis. As shown in FIG. 1B, each sensing layer includes a plurality of parallel sensing lines separately plated on two transparent substrates. By binding two certain transparent substrates, the sensing layers as shown in FIG. 1A can be formed. Thus, the touch panel can compute the position of the touch point by utilizing a circuit to detect the voltage variation of each sensing line in both X- and Y-axial directions.

However, the double sensing layers need an additional transparent substrate or an insulation layer. Therefore, it always increases the thickness and production cost of the touch panel.

In order to deal with the above issue, a single sensing layer for the touch panel is disclosed in U.S. Pat. No. 6,961,049. As shown in FIG. 1C, the sensing layer includes a plurality of parallel rectangular sensing lines 321 to 329, each of which is connected to a detecting circuit through it's left end a and right end b. The detecting circuit can compute the Y-coordinate of a touch position in accordance with the coordinates of the sensing lines with the maximum voltage variation or with interpolation. Additionally, the detecting circuit also can detect the voltages at left and right ends of the sensing lines, and then compute the X-coordinate of the touch position with X=L·Vₗ(Vₗ+Vᵣ), wherein L is the length from one end of the sensing line to the other end thereof in X-axial direction, and Vₗ and Vᵣ respectively represent the voltages at left and right ends. However, all ends of the sensing lines in the sensing layer are connected to a multiplexer, which can switch between the sensing points to connect one of the ends to the detecting circuit. Unfortunately, more sensing points always result in more switching times of the multiplexer, and, eventually, cause slower refresh rate. In this circumstance, the touch position computed by the above-mentioned formula have more errors in the real touch position, and the resolution and signal-to-noise ratio are low.

Besides the prior arts mentioned above, different sensing structures of touch panels disclosed in U.S. Pat. Nos. 4,071,691, 4,455,452, 4,550,221, 4,639,720, 4,733,222, 4,980,519, 6,147,680, 6,188,391, 7,129,935, 7,202,859, 7,218,124, 4,071,691, 6,297,811, 5,650,597, 6,825,833, 6,961,049, 5,861,583 and 5,305,017, are all have the same defect.

### SUMMARY OF THE INVENTION

The present invention is to provide a touch panel with a single sensing layer, which can increase the sensing refresh rate and improve the coordinate computing formulas.

The touch panel of the present invention includes a plurality of sensing lines extending along a first direction and arranged in a row along a second direction. Each of the sensing lines has a first end and a second end, and is electrically connected to a detecting circuit, respectively, along the first direction. In addition, each of the sensing lines is connected to adjacent one in series through the first end or the second end to form an S-shaped structure. The detecting circuit computes a coordinate in the first and second directions of a touch position in accordance with voltage variation at the first and second ends of the sensing lines.

The sensing layer comprises N sensing lines. One end of an i^{th} (i=2, 3, 4 . . . (N−1)) sensing line and one end of an (i−1)^{th} sensing line are electrically connected to each other, and then electrically connected to the detecting circuit. In addition, the other end of the i^{th} sensing line and one end of an (i+1)^{th} sensing line are electrically connected to each other, and then electrically connected to the detecting circuit. The first end of a first sensing line and the second end of an N^{th} sensing line are respectively connected to the detecting circuit directly. Alternatively, the first end of the first sensing line and the second end of the N^{th} sensing line can be electrically connected to each other and then electrically connected to the detecting circuit.

The above-mentioned first and second directions are individually X-axial and Y-axial directions, or Y-axial and X-axial directions.

Preferably, the above-mentioned sensing lines are rectangular, trapezoidal, polygonal, elliptic, bar-shaped or irregular. Alternatively, it can include a plurality of rhombus-shaped, triangular, hexagonal, rectangular, polygonal, elliptic, circular or irregular sensor units connected by a sensing conductive line.

The touch panel further includes a first substrate, and the sensing layer is disposed on the first substrate by plating, physical deposition, chemical deposition, printing, sputtering, gluing or coating. The touch panel also can include a protective layer disposed on one side of the sensing layer opposite to the first substrate, and the protective layer is attached on the first substrate by a first filling layer. Alternatively, the sensing layer can be disposed on the protective layer by plating, physical deposition, chemical deposition, printing, sputtering, gluing or coating, and then the sensing layer and the protective layer are attached on the first substrate by gluing. Moreover, the touch panel can further include an anti-reflection layer, a hardened protective layer or a dustproof layer, which is disposed on one side of the protective layer opposite to the sensing layer. The touch panel also can include an anti-interference layer or a second substrate, which is disposed on one side of the first substrate opposite to the sensing layer. The anti-interference layer is disposed on the first or second substrate by plating, physical deposition, chemical deposition, printing, sputtering, gluing or coating. The anti-interference layer or the second substrate is attached on the first substrate by a second filling layer.

Each of the first substrate, second substrate and protective layer is a transparent or opaque substrate, and the material thereof preferably includes glass, plastic, ceramics, rubber, a circuit substrate or an insulation material.

Preferably, the material of the sensing layer and anti-interference layer includes ITO, AZO, SnO₂, copper, aluminum, silver, gold, metal or an electrically conductive material.

To achieve the above, the touch panel in accordance with the present invention includes a sensing layer, which has a plurality of sensing lines extending along a first direction and arranged in a row along a second direction. Each of the sensing lines has a first end and a second end, and at least one of the first and second ends is connected to a detecting circuit. In addition, at least one resistor is disposed between and connected to the adjacent sensing lines. The detecting circuit computes a coordinate in the first and second directions of a touch position in accordance with voltage variation of the sensing lines.

The resistor is an electronic element, a transparent resistance layer or an opaque resistance layer. The transparent resistance layer includes ITO, AZO or SnO₂, and the opaque resistance layer includes carbon, graphite or a thin film resistance formed by a semiconductor manufacturing process. Otherwise, the sensing lines and the detecting circuit are connected by a plurality of conductive lines, and the resistance values of the conductive lines are lower than that of the at least one resistor.

Preferably, the resistor is a connecting line for connecting two adjacent sensing lines. The sensing lines and the connecting lines are preferably made of the same material and are integrally combined. Moreover, the sensing lines and the connecting lines are interlacingly connected to form a surface with a plurality of holes, and each hole is surrounded by two adjacent sensing lines and two connecting lines, which are perpendicular to each other. The first and second ends of each sensing line are respectively connected to the detecting circuit; alternatively, either the first end or the second end of each the sensing line is connected to the detecting circuit.

To achieve the above, the touch panel in accordance with the present invention includes a sensing layer having a plurality of sensing lines extending along a first direction and arranged in a row along a second direction. Each of the sensing lines has a first end and a second end along the first direction, and the first and second ends are connected to a detecting circuit, respectively. Lengths of the first and second ends are not equal. Thus, the detecting circuit computes a coordinate in the first and second directions of a touch position in accordance with voltage variation at the first and second ends of the sensing lines.

Preferably, the sensing lines are trapezoidal, polygonal, elliptic, bar-shaped or irregular.

Additionally, the touch panel in accordance with the present invention includes a sensing layer having a plurality of sensing lines extending toward a first direction and arranged in a row along a second direction. Each of the sensing lines has a first end and a second end along the first direction, and the first and second ends are connected to a detecting circuit respectively. Thus, the detecting circuit computes a coordinate in the first direction of a touch position in accordance with ratios of the sums and the differences of voltage variation at the first and second ends of the sensing line.

Furthermore, the detecting circuit computes the coordinate in the first direction of the touch position in accordance with at least one of the sensing lines with the maximum voltage variation. The detecting circuit computes the coordinate in the first direction of the touch position by a formula, X=(V_{d1}−V_{c1})/(V_{c1}+V_{d1}), where Vc₁ is the voltage variation at the first end of the sensing line with the maximum voltage variation and V_{d1} is the voltage variation at the second end of the sensing line.

Alternatively, the coordinate can be obtained according to a plurality of sensing lines with maximum voltage variation. The detecting circuit computes the coordinate in the first direction of the touch position by a formula,

$$X = \frac{{\sum }_{i = 1}^{M} ( {V}_{di} - {V}_{ci} )}{{\sum }_{i = 1}^{M} ( {V}_{ci} + {V}_{di} )} ,$$

where M is the number of the sensing lines with the maximum voltage variation, V_{ci} is the voltage variation at the first end of the sensing line i (i=1, 2, 3 . . . M) and V_{di} is the voltage variation at the second end of the sensing line i.

Meanwhile, the detecting circuit can compute a coordinate in the second direction of the touch position in accordance with the center of gravity of the voltage variation of the sensing lines. The detecting circuit computes the coordinate in the second direction of the touch position in accordance with the voltage variation at the first end of the sensing line i by a formula,

$$Y = \frac{{\sum }_{i = 1}^{N} {Y}_{i} \cdot {V}_{ci}}{{\sum }_{i = 1}^{N} {V}_{ci}} ,$$

where N is the number of the sensing lines of the sensing layer, Yᵢ is the coordinate in the second direction of the sensing line i (i=1, 2, 3 . . . N) and V_{ci} is the voltage variation at the first end of the sensing line i. The detecting circuit can also computes the coordinate in the second direction of the touch position in accordance with the voltage variation at the second end of the sensing line i by a formula,

$$Y = \frac{{\sum }_{i = 1}^{N} {Y}_{i} \cdot {V}_{di}}{{\sum }_{i = 1}^{N} {V}_{di}} ,$$

where V_{di} is the voltage variation at the second end of the sensing line i. Further, the detecting circuit can also computes the coordinate in the second direction of the touch position in accordance with the voltage variation at the first and second end of the sensing line i by a formula,

$$Y = \frac{{\sum }_{i = 1}^{N} {Y}_{i} \cdot ( {V}_{ci} + {V}_{di} )}{{\sum }_{i = 1}^{N} ( {V}_{ci} + {V}_{di} )} .$$

### BRIEF DESCRIPTION OF THE DRAWINGS

The invention will become more fully understood from the detailed description and accompanying drawings, which are given for illustration only, and thus are not limitative of the present invention, and wherein:

FIGS. 1A to 1C are schematic diagrams of a sensing layer of a conventional touch panel;

FIGS. 2A, 3A and 3B are schematic diagrams of a sensing layer of a touch panel according to a first preferred embodiment of the present invention;

FIGS. 2B and 3C are schematic diagrams showing the steps indicating the switching order of the sensing layer as shown in FIGS. 2A, 3A and 3B;

FIG. 4 is a schematic diagram of another sensing layer of the touch panel according to the preferred embodiment of the present invention;

FIGS. 5A and 5B are schematic diagrams of a sensing layer of a touch panel according to a second preferred embodiment of the present invention;

FIG. 5C is a schematic diagram showing the voltage variation of the pressed sensing lines as shown in FIG. 5A;

FIG. 5D is a schematic diagram showing the voltage variation of the pressed sensing lines of the conventional sensing layer;

FIGS. 6A and 6B are schematic diagrams showing the sensing layer of FIG. 5B that uses connecting lines as resistors;

FIGS. 7A and 7B are schematic diagrams of another sensing layer of the touch panel according to the preferred embodiment of the present invention;

FIG. 8 is a schematic diagram of a coordinate computing formula of the sensing layer of the touch panel according to the preferred embodiment of the present invention; and

FIGS. 9A and 9C are schematic diagrams showing several touch panels according to the preferred embodiment of the present invention.

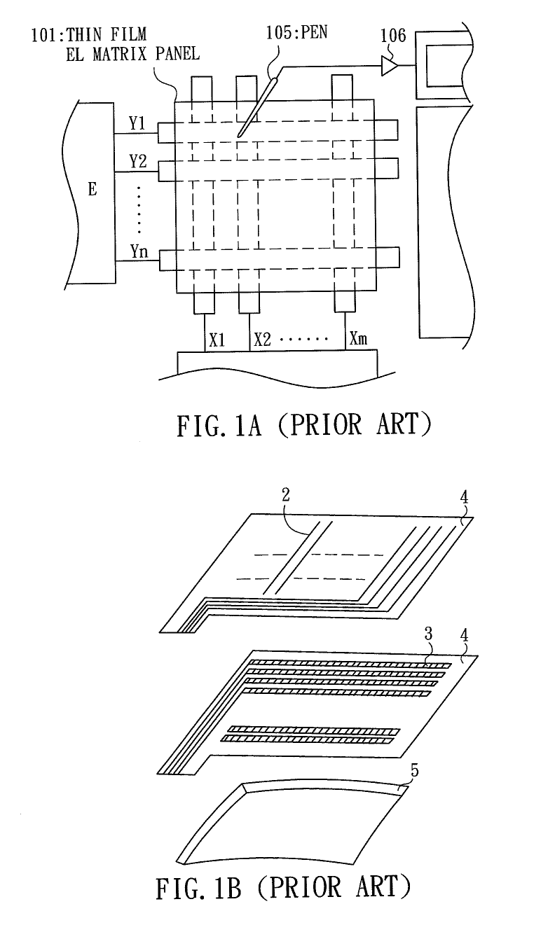

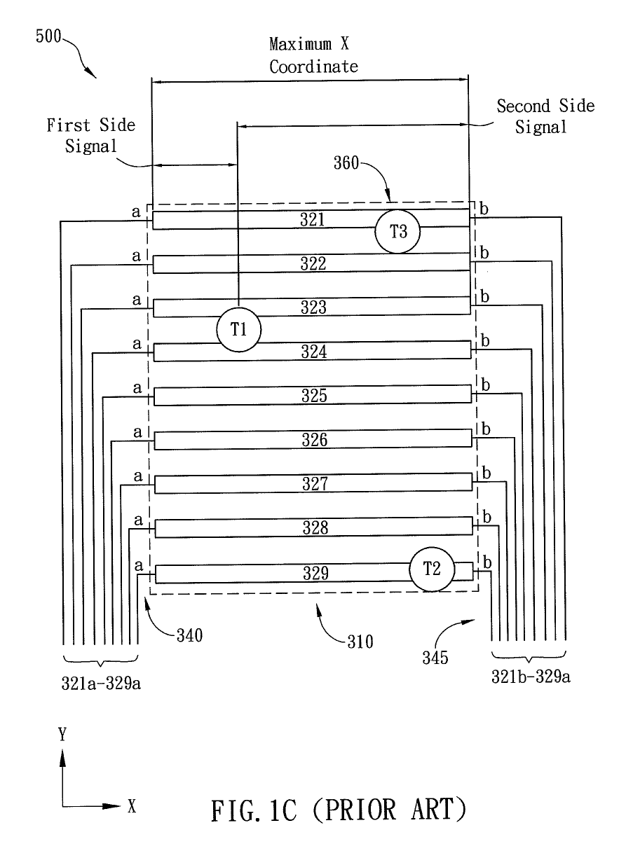

### DETAILED DESCRIPTION OF THE INVENTION

The present invention will be apparent from the following detailed description, which proceeds with reference to the accompanying drawings, wherein the same references relate to the same elements.

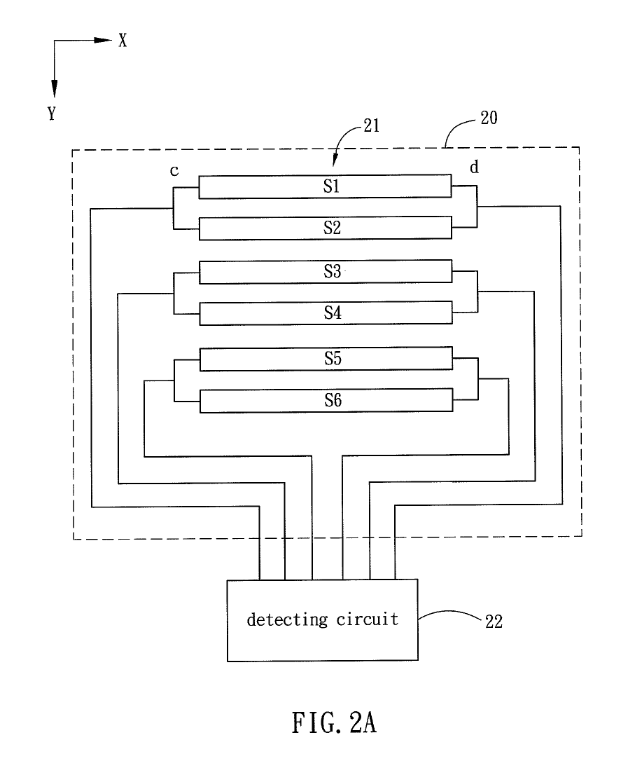

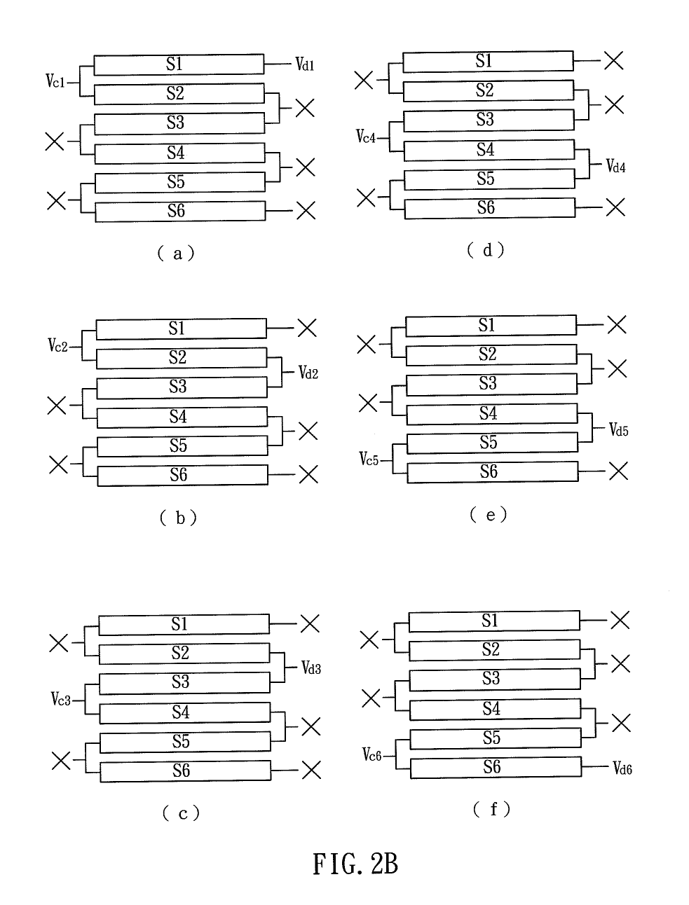

FIG. 2A is a schematic view of a sensing layer of a touch panel according to a first embodiment of the present invention. As shown in FIG. 2A, a sensing layer 21 of a touch panel 20 includes a plurality of sensing lines S1 to S6 extending toward an X-axial direction and arranged in a row along a Y-axial direction. Each of the sensing lines has a first end c and a second end d. Each of the sensing lines S1 to S6 is electrically connected to another one through the first end c or the second ends d, and then electrically connected to the detecting circuit 22. Thus, the detecting circuit 22 can compute a coordinate in the X-axial and Y-axial directions of a touch position in accordance with voltage variation at the first and second ends of the sensing lines S1 to S6.

Additionally, the second end d of the first sensing line S1 is connected to the detecting circuit 22 directly along the Y-axial direction. The connection between the sensing lines S1 to S6 and the detecting circuit 22 is shown in FIG. 2. The second sensing line S2 and the first sensing line S1 are electrically connected through their first ends c, and then electrically connected to the detecting circuit 22. The second sensing line S2 and the third sensing line S3 are electrically connected through their second ends d, and then electrically connected to the detecting circuit 22. According to the same rule, the first end c of the forth sensing line S4 is electrically connected to the third sensing line S3 and then electrically connected to the detecting circuit 22, and the second end d of the forth sensing line S4 is electrically connected to the fifth sensing line S6 and then electrically connected to the detecting circuit 22. The sixth sensing line S6 is connected to the fifth sensing line S5 through the first end c and then connected to the detecting circuit 22, and the second end d of the sixth sensing line S6 is connected to the detecting circuit 22 directly. In brief, each of the sensing lines is connected to adjacent one in series through the first end c and the second end d to form an S-shaped structure.

As shown in FIG. 2B, the steps of switching sensing points for the sensing layer are shown in FIG. 2A by the following steps (a)→(b)→(c) →(d)→(e)→(f), and then repeating circularly. When the sensing layer is in the step (a), both ends of the first sensing line S1 are conducted to the detecting circuit so that the voltage variation thereof can be measured as V_{c1} and V_{d1}, respectively. Similarly, in the step (b), the both ends of the second sensing line S2 are conducted to the detecting circuit, so that the voltage variation thereof can be measured as V_{c2} and V_{d2}, respectively. The steps (c), (d), (e) and (f) are similar to the step (a) or (b). In such a circumstance, the voltage variation at both ends of every sensing line can still be measured even according to about a half of the sensing points.

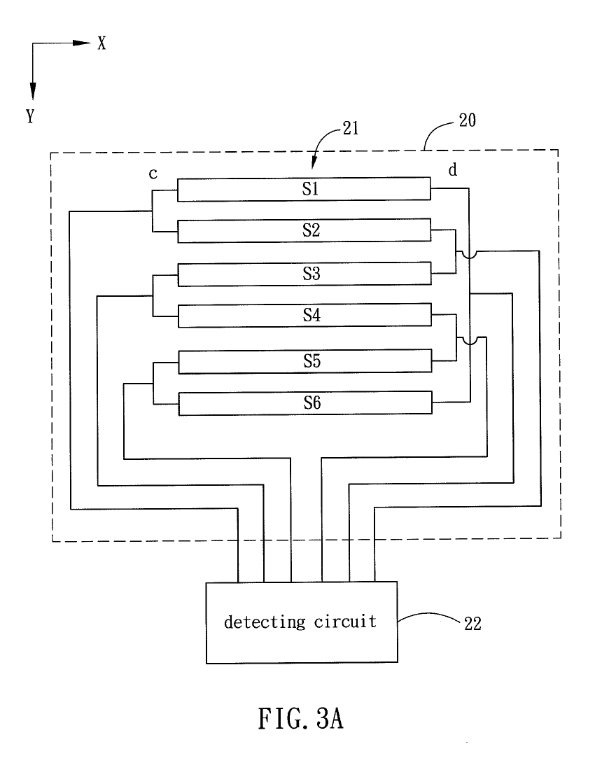

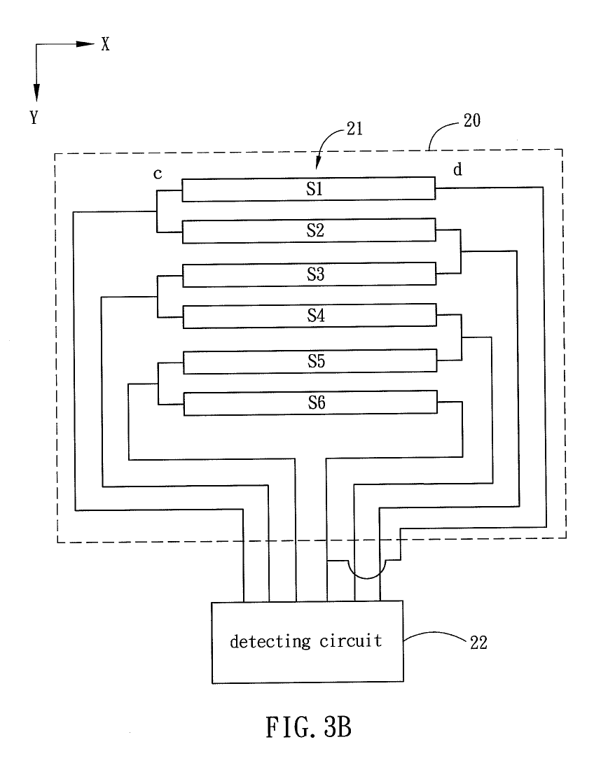

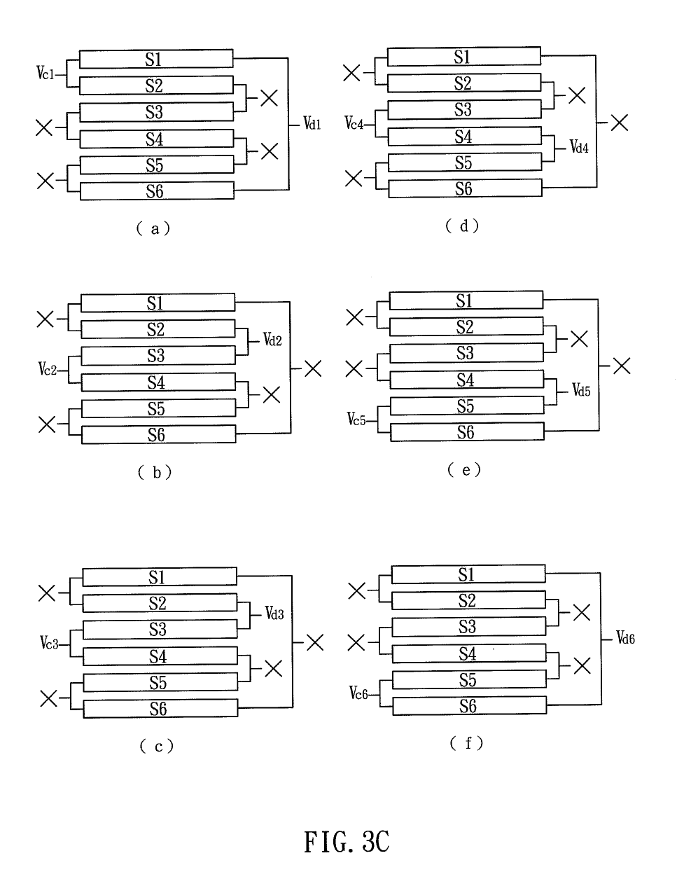

The connections shown in FIGS. 3A and 3B are similar to that shown in FIG. 2A, and the only difference therebetween is in that the first sensing line S1 and the sixth sensing line S6 are electrically connected to each other before electrically connected to the detecting circuit 22, but not connected to the detecting circuit 22 directly. As shown in FIG. 3A, the first sensing line S1 and the sixth sensing line S6 can be electrically connected to each other on the touch panel 20 and then connected to the detecting circuit 22. As shown in FIG. 3B, they also can be electrically connected after extending out of the touch panel 20, respectively. If the first sensing line S1 and the sixth sensing line S6 are electrically connected on the touch panel 20, an insulator must be disposed to isolate them from other conductive lines. The switching order for the touch panel in FIGS. 3A and 3B is to follow the steps (a)→(b)→(c)→(d)→(e)→(f), and then repeat circularly.

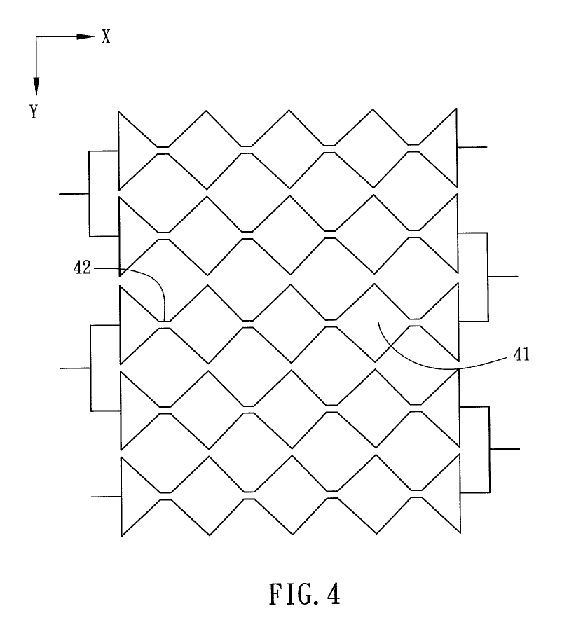

Alternatively, the sensing lines can include a plurality of connected sensor units. As shown in FIG. 4, the sensor units 41 are connected by sensing conductive lines 42 to form the sensing lines extending toward X-axial direction, and then the sensing lines are arranged along Y-axial direction in a row to form the sensing layer. The shapes of the sensor units 42 can be, for example but not limited to, rhombus-shaped, triangular, hexagonal, rectangular, polygonal, elliptic, circular or irregular.

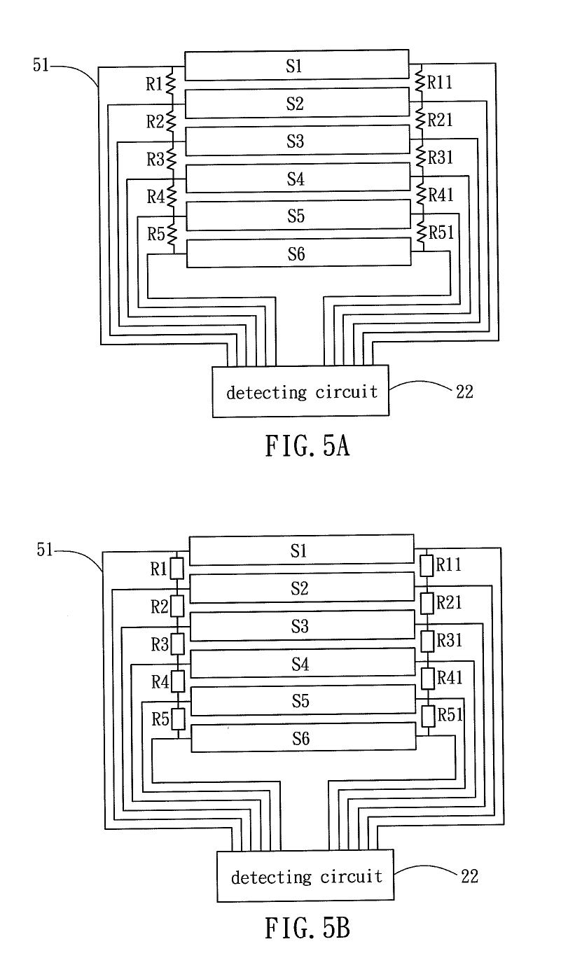

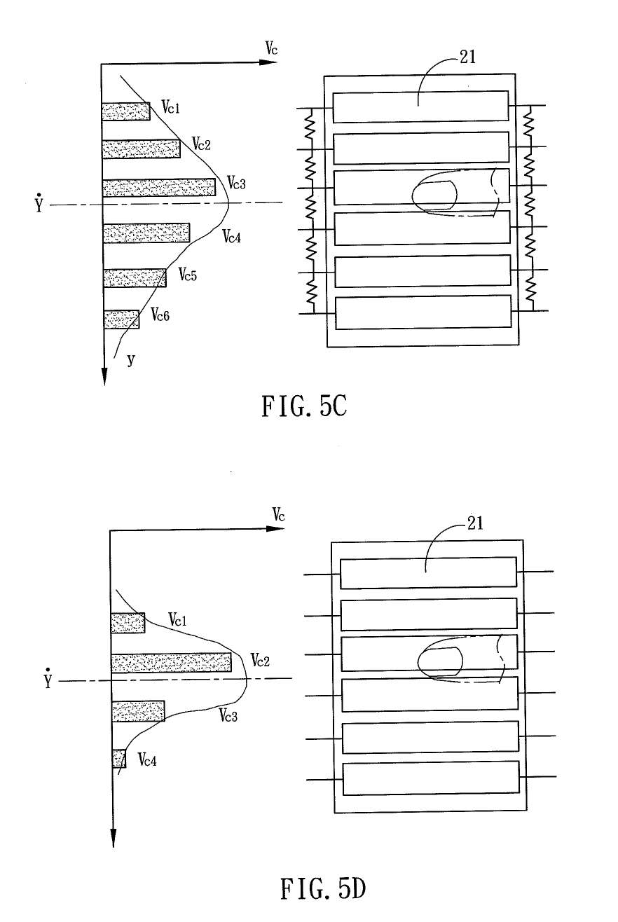

The touch panel according to a second embodiment of the present invention is shown in FIGS. 5A and 5B. A plurality of sensing lines extending toward X-axial direction and arranged in a row along Y-axial direction. Each of the sensing lines has a first end and a second end in X-axial direction, and at least one of the first and second ends is connected to a detecting circuit. In addition, at least one resistor is disposed between and connected to the adjacent sensing lines. In this embodiment, a resistor R1 is disposed between the first ends of the first sensing line S1 and the second sensing line S2, and a resistor R11 is disposed between their second ends. Similarly, a resistor R2 is disposed between the first ends of the second sensing line S2 and the third sensing line S3, and a resistor R21 is disposed between their second ends. Other resistors can be disposed to connect the rest sensing lines according to, but not limited to, the same connection mode. Moreover, the amount and the connection mode of the resistors can be adjusted depending on practical needs. Thus, the detecting circuit can compute a coordinate in X-axial and Y-axial directions of a touch position in accordance with voltage variation of the sensing lines.

The sensing lines and the detecting circuit are connected by a plurality of conductive lines 51, which are good conductors with resistance values lower than that of the resistor.

The resistor can be an electronic element, a transparent resistance layer or an opaque resistance layer. The transparent resistance layer includes ITO, AZO or SnO2, and the opaque resistance layer includes carbon, graphite or a thin film resistance formed by a semiconductor manufacturing process. Furthermore, the sensing lines and the detecting circuit are connected through a plurality of conductive lines, and the resistance values of the conductive lines are lower than that of the at least one resistor.

In this embodiment, every two adjacent sensing lines are connected by the resistor so that the signal variation of the current flowing through the sensing lines at the touch position can be distributed to other nearby sensing lines. Therefore, the voltage variation is shown in FIG. 5C once the sensing lines are pressed by the finger. Comparatively, the voltage variation of the conventional sensing layers is shown in FIG. 5D as the sensing lines are pressed by the finger. In comparison between the above two results, the present invention has a broader distribution that can not only reduce the digitalized influence of the sensing lines but also provide a smoother coordinate change while the touch position is moving.

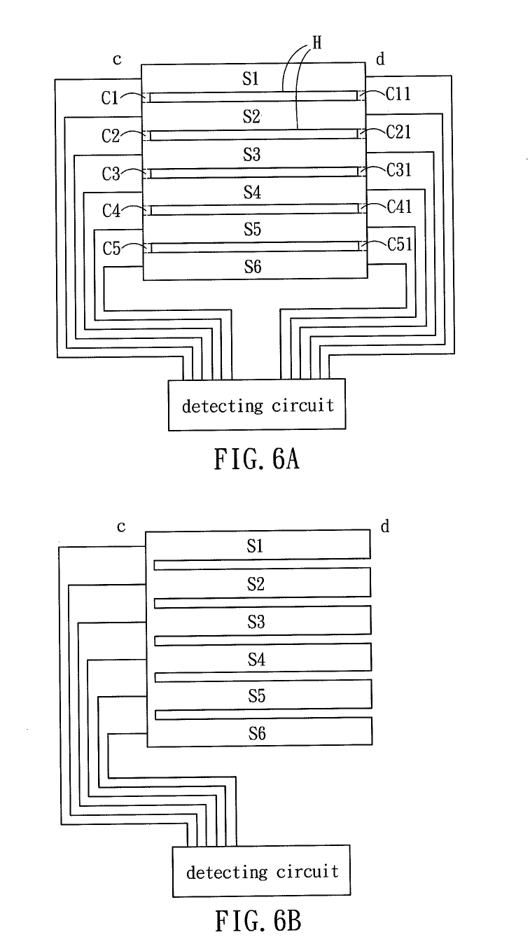

The resistor can be a connecting line. As shown in FIG. 6A, the first sensing line S1 and the second sensing line S2 are connected through the connecting lines C1 and C11. Then, the second sensing line S2 and the third sensing line S3 are connected through the connecting lines C2 and C21. Other connecting lines can be disposed to connect the rest sensing lines according to the same connection mode. Preferably, the sensing lines and connecting lines are made of the same material and are integrally combined. Additionally, the sensing lines and the connecting lines are interlacingly connected to form a surface with a plurality of holes H. Each of the holes H is surrounded by two adjacent sensing lines and two adjacent connecting lines, and the sensing lines and the connecting lines are perpendicular to each other. As shown in FIG. 6B, the first end c and the second end d of each sensing line can be connected to the detecting circuit respectively, or either the first end c or the second end d of the sensing line is connected to the detecting circuit.

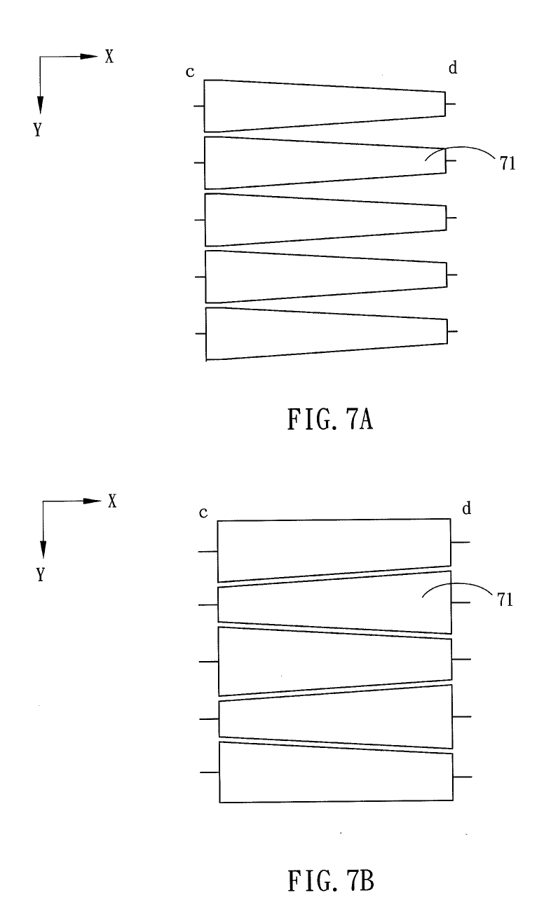

As shown in FIG. 7A, the sensing layer of a touch panel according to a third preferred embodiment of the present invention includes a plurality of trapezoidal sensing lines arranged in a row along the same direction. Each of the trapezoidal sensing lines has the first end c and the second end d along X-axial direction, and lengths of the first end c and second end d are not equal. By the configuration of the trapezoidal sensing lines, the more the finger-contacting area of the sensing lines the touch-controlling area is broader when the touch position is closer to the first end c of the sensing lines. In this circumstance, the voltage variation at the first end c of the trapezoidal sensing lines is more significant than that of the rectangular sensing lines. Thus, the resolution and signal-to-noise ratio must be better by using the voltage variation at the first end c for computing the X-axial coordinate. Otherwise, as shown in FIG. 7B, the sensing layer of the present invention can include a plurality of trapezoidal sensing lines, which are arranged interlacingly with two opposite directions. This arrangement has higher voltages at the first ends c of even sensing lines and the second ends d of odd sensing lines. However, shapes of the sensing lines do not have to be rectangular or trapezoidal, and can be polygonal, elliptic, bar-shaped or irregular depending on practical needs.

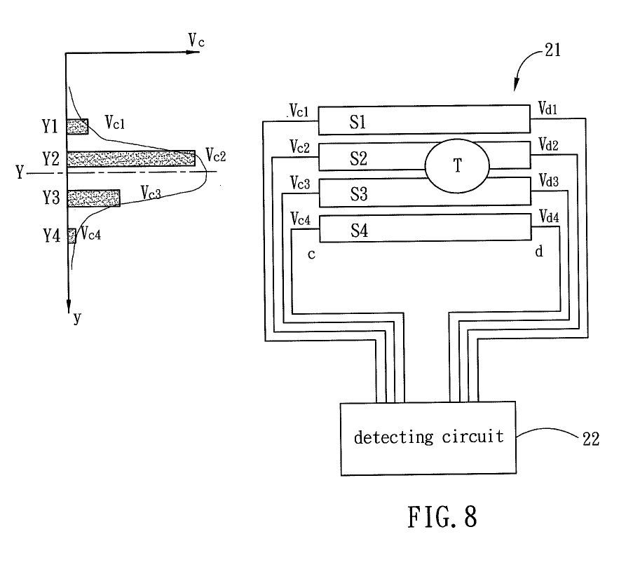

The sensing layer and the coordinate computing formulas thereof of the touch panel according to the preferred embodiment of the present invention are shown in FIG. 8. The sensing layer includes a plurality of sensing lines S1 to S4 extended toward X-axial direction and arranged in a row along Y-axial direction. The sensing layer of the present embodiment includes, for example but not limited to, four sensing lines. In contrast, the amount, shape and connection mode of the sensing lines can be adjusted depending on practical needs so that the sensing layer can be a sensing layer with the S-shaped connection mode in FIGS. 2A and 2B, a sensing layer including the sensing lines connected with the resistors in FIGS. 5A and 5B, a sensing layer including the sensing lines connected with the connecting lines in FIGS. 6A and 6B, or the trapezoidal sensing lines in FIGS. 7A and 7B. Each of the sensing lines S1 to S4 has a first end c and a second end d connected to a detecting circuit 22, respectively. Thus, the detecting circuit computes a coordinate in X-axial direction of a touch position T in accordance with ratios of the sums and the differences of voltage variation at the first and second ends of the sensing lines. There are two preferred computing formulas, which will be described hereinafter. One is to compute the coordinate in accordance with single one sensing line, which has the maximum voltage variation such as the second sensing line S2 in the present embodiment. Then, the voltage variation at two ends are V_{c2} and V_{d2}, and the detecting circuit computes the X-coordinate of the touch position by a formula, X=(V_{d2}−V_{c2})/(V_{c2}+V_{d2}). The other one is to compute the coordinate in accordance with a plurality of the sensing lines, which have the maximum voltage variation. In this aspect, all of the four sensing lines in FIG. 2 are included and the computing formula is:

$$\begin{matrix}X = \frac{{\sum }_{i = 1}^{4} ( {V}_{di} - {V}_{ci} )}{{\sum }_{i = 1}^{4} ( {V}_{ci} + {V}_{di} )} \\ = \frac{( {V}_{d 1} - {V}_{c 1} ) + ( {V}_{d 2} - {V}_{c 2} ) + ( {V}_{d 3} - {V}_{c 3} ) + ( {V}_{d 4} - {V}_{c 4} )}{( {V}_{c 1} + {V}_{d 1} ) + ( {V}_{c 2} + {V}_{d 2} ) + ( {V}_{c 3} + {V}_{d 3} ) + ( {V}_{c 4} + {V}_{d 4} )} .\end{matrix}$$

As to the computing formula of the present invention, in order that the numerator of the obtained X-coordinate results from the differences of voltage variation, the intercept of the obtained X-coordinate can be zero when the touch position is at the center of the sensing line. In contrast, the conventional computing formula always obtains non-zero value in the same circumstance so that the program for computing coordinate has to save those additional non-zero values. Also, the non-zero values vary easily between different resistance values of the sensing lines. Apparently, the conventional computing formula is inconvenient for application, and usually generates a worse resolution and signal-to-noise ratio as well.

Otherwise, as to the Y-coordinate, the detecting circuit computes it in accordance with the center of gravity of the voltage variation of the sensing lines. There are three preferred computing formulas for it, which will be described hereinafter. The first one is to compute the Y-coordinate in accordance with the voltage variation at the first ends c of the sensing lines S1 to S4. The Y-coordinates of those four sensing lines can be Y1, Y2, Y3 and Y4, and then the detecting circuit can compute the Y-coordinate of the touch position by a formula,

$$\begin{matrix}Y = \frac{{\sum }_{i = 1}^{4} {Y}_{i} \cdot {V}_{ci}}{{\sum }_{i = 1}^{4} {V}_{ci}} \\ = \frac{{Y}_{1} \cdot {V}_{c 1} + {Y}_{2} \cdot {V}_{c 2} + {Y}_{3} \cdot {V}_{c 3} + {Y}_{4} \cdot {V}_{c 4}}{{V}_{c 1} + {V}_{c 2} + {V}_{c 3} + {V}_{c 4}} .\end{matrix}$$

The second preferred computing formula computes the Y-coordinate in accordance with the voltage variation at the second ends d of the sensing lines S1 to S4, and the computing formula is

$$\begin{matrix}Y = \frac{{\sum }_{i = 1}^{4} {Y}_{i} \cdot {V}_{di}}{{\sum }_{i = 1}^{4} {V}_{di}} \\ = \frac{{Y}_{1} \cdot {V}_{d 1} + {Y}_{2} \cdot {V}_{d 2} + {Y}_{3} \cdot {V}_{d 3} + {Y}_{4} \cdot {V}_{d 4}}{{V}_{d 1} + {V}_{d 2} + {V}_{d 3} + {V}_{d 4}} .\end{matrix}$$

The third computing formula computes the Y-coordinate in accordance with the voltage variation at the both ends c and d, and the computing formula is

$$\begin{matrix}Y = \frac{{\sum }_{i = 1}^{4} {Y}_{i} \cdot ( {V}_{ci} + {V}_{di} )}{{\sum }_{i = 1}^{4} ( {V}_{ci} + {V}_{di} )} \\ = \frac{{Y}_{1} \cdot ( {V}_{c 1} + {V}_{d 1} ) + {Y}_{2} \cdot ( {V}_{c 2} + {V}_{d 2} ) + {Y}_{3} \cdot ( {V}_{c 3} + {V}_{d 3} ) + {Y}_{4} \cdot ( {V}_{c 4} + {V}_{d 4} )}{( {V}_{c 1} + {V}_{d 1} ) + ( {V}_{c 2} + {V}_{d 2} ) + ( {V}_{c 3} + {V}_{d 3} ) + ( {V}_{c 4} + {V}_{d 4} )} .\end{matrix}$$

As to the obtained Y-coordinate in accordance with the computing formula of the present invention, it results from the center of gravity of the voltage variation of a plurality of the sensing lines so that it is more accurate than the Y-coordinate obtained by the conventional way, which uses the interpolation to compute the voltage variation at two sensing lines having the maximum voltage variation.

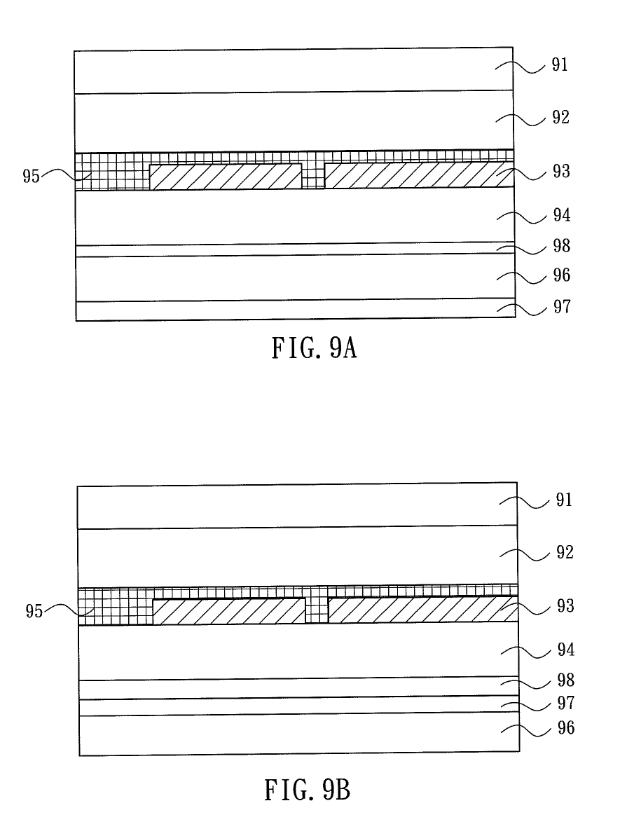

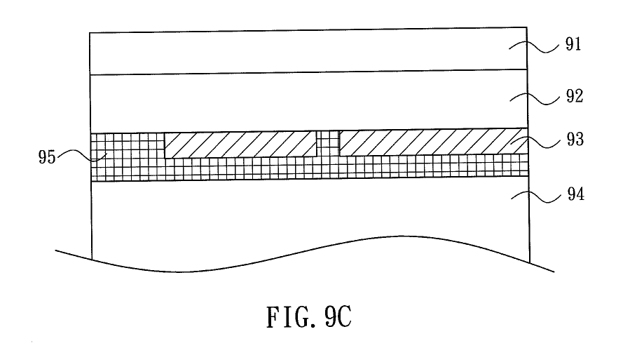

As shown in FIGS. 9A and 9B, the touch panel of the present invention further includes a first substrate 94, and the sensing layer 93 is disposed on the first substrate 94 by plating, physical deposition, chemical deposition, printing, sputtering, gluing or coating. Then, a protective layer 92 is attached on one side of the sensing layer 93 opposite to the first substrate 94 by a first filling layer 95. The protective layer 92 can be further plated with an anti-reflection layer 91; however, whether the anti-interference layer 91 is disposed depends on practical needs. Alternatively, the anti-reflection layer 91 can be replaced with a hardened protective layer or a dustproof layer. As shown in FIG. 9C, the sensing layer 93 also can be disposed on the back surface of the protective layer 92 by plating, physical deposition, chemical deposition, printing, sputtering, gluing or coating, and then the sensing layer 93 and the protective layer 92 are attached on the first substrate 94 by the first filling layer 95.

Preferably, the touch panel further includes a second substrate 96 and an anti-interference layer 97, which is disposed on the second substrate 96 by plating, physical deposition, chemical deposition, printing, sputtering, gluing or coating. Then, the anti-interference layer 97 and the second substrate 96 are attached on the side of the first substrate 94 opposite to the sensing layer 93. However, the anti-interference layer 97 can be disposed on the first substrate 94 directly by plating, physical deposition, chemical deposition, printing, sputtering, gluing or coating without disposing the second substrate 96 and the second filling layer 98.

Each of the first substrate 94, the second substrate 96 and the protective layer 92 can be a transparent or opaque substrate, and the material thereof is preferably glass, plastic, ceramics, rubber, a circuit substrate or an insulation material.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A touch panel, comprising:
a sensing layer comprising a plurality of sensing lines extending along a first direction and arranged in a row along a second direction, wherein each of the sensing lines has a first end and a second end, and electrically connected to a detecting circuit, and each of the sensing lines is connected to adjacent one in series through the first end or the second end;
wherein the detecting circuit computes a coordinate in the first and second directions of a touch position in accordance with voltage variation at the first and second ends of the sensing lines.

2. The touch panel of claim 1, wherein the sensing layer comprises N sensing lines, one end of an i^{th} sensing line and one end of an (i−1)^{th} sensing line are electrically connected to each other and then electrically connected to the detecting circuit, and the other end of the i^{th} sensing line and one end of an (i+1)^{th} sensing line are electrically connected to each other and then electrically connected to the detecting circuit, where i=2, 3, 4 . . . (N−1).

3. The touch panel of claim 2, wherein the first end of a first sensing line and the second end of an N^{th} sensing line are respectively connected to the detecting circuit directly, or electrically connected to each other and then electrically connected to the detecting circuit.

4. The touch panel of claim 1, wherein the sensing lines are rectangular, trapezoidal, polygonal, elliptic, bar-shaped or irregular.

5. The touch panel of claim 1, wherein the sensing line comprises a plurality of sensor units which are electrically connected by a sensing conductive line, and the sensor unit is rhombus-shaped, triangular, hexagonal, rectangular, polygonal, elliptic, circular or irregular.

6. The touch panel of claim 1, wherein a material of the sensing layer comprises ITO, AZO, SnO₂, copper, aluminum, silver, gold, metal or electrically conductive material.

7. The touch panel of claim 1, further comprising:
a first substrate, wherein the sensing layer is disposed on the first substrate by plating, physical deposition, chemical deposition, printing, sputtering, gluing or coating, and the first substrate is a transparent or opaque substrate, and a material of the first substrate comprises glass, plastic, ceramics, rubber, circuit substrate or insulation material.

8. The touch panel of claim 7, further comprising:
a protective layer disposed on one side of the sensing layer opposite to the first substrate, wherein the protective layer is a transparent or opaque substrate, and a material of the protective layer comprises glass, plastic, ceramics, rubber, circuit substrate or insulation material.

9. The touch panel of claim 8, wherein the protective layer is attached on the first substrate by a first filling layer.

10. The touch panel of claim 8, wherein the sensing layer is disposed on the protective layer by plating, physical deposition, chemical deposition, printing, sputtering, gluing or coating, and then the sensing layer and the protective layer are attached on the first substrate by gluing.

11. The touch panel of claim 8, further comprising:
an anti-reflection layer, a hardened protective layer or a dustproof layer disposed on one side of the protective layer opposite to the sensing layer.

12. The touch panel of claim 7, further comprising:
an anti-interference layer and a second substrate disposed on one side of the first substrate opposite to the sensing layer, wherein a material of the anti-interference layer comprises ITO, AZO, SnO₂, copper, aluminum, silver, gold, metal or electrically conductive material, and the second substrate is a transparent or opaque substrate, and a material of the second substrate comprises glass, plastic, ceramics, rubber, circuit substrate or insulation material.

13. The touch panel of claim 12, wherein the anti-interference layer is disposed on the first or second substrate by plating, physical deposition, chemical deposition, printing, sputtering, gluing or coating.

14. The touch panel of claim 12, wherein the anti-interference layer or the second substrate is attached on the first substrate by a second filling layer.

15. A touch panel, comprising:
a sensing layer comprising a plurality of sensing lines extending along a first direction and arranged in a row along a second direction, wherein each of the sensing lines has a first end and a second end, at least one of the first and second ends is connected to a detecting circuit, and at least one resistor is disposed between and connected to the adjacent sensing lines;
wherein the detecting circuit computes a coordinate in the first and second directions of a touch position in accordance with voltage variation of the sensing lines.

16. The touch panel of claim 15, wherein the resistor is an electronic element, a transparent resistance layer or an opaque resistance layer, the transparent resistance comprises ITO, AZO or SnO₂, and the opaque resistance layer comprises carbon, graphite or a thin film resistance formed by a semiconductor manufacturing process.

17. The touch panel of claim 15, wherein the sensing lines and the detecting circuit are connected through a plurality of conductive lines, and the resistance values of the conductive lines are lower than that of the at least one resistor.

18. The touch panel of claim 15, wherein the resistor is a connection line for connecting two adjacent sensing lines.

19. The touch panel of claim 18, wherein the sensing lines and the connecting lines are made of the same material and are integrally combined.

20. The touch panel of claim 18, wherein the sensing lines and the connecting lines are interlacingly connected to form a surface with a plurality of holes, and the sensing lines and the connecting lines are perpendicular to each other.

21. The touch panel of claim 20, wherein each of the holes is surrounded by two adjacent sensing lines and two adjacent connecting lines.

22. The touch panel of claim 15, wherein the first and second ends of each sensing line are respectively connected to the detecting circuit, or either the first end or the second end of each the sensing line is connected to the detecting circuit.

23. A touch panel, comprising:
a sensing layer comprising a plurality of sensing lines extending along a first direction and arranged in a row along a second direction, wherein each of the sensing lines has a first end and a second end, the first and second ends are connected to a detecting circuit, respectively, and lengths of the first and second ends are not equal;
wherein the detecting circuit computes a coordinate in the first and second directions of a touch position in accordance with voltage variation at the first and second ends of the sensing lines.

24. A touch panel, comprising:
a sensing layer comprising a plurality of sensing lines extending along a first direction and arranged in a row along a second direction, wherein each of the sensing lines has a first end and a second end, and the first and second ends are connected to a detecting circuit, respectively,
wherein the detecting circuit computes a coordinate in the first direction of a touch position in accordance with ratios of the sums and the differences of voltage variation at the first and second ends of the sensing line.

25. The touch panel of claim 24, wherein the detecting circuit computes the coordinate in the first direction of the touch position in accordance with at least one of the sensing lines with the maximum voltage variation.

26. The touch panel of claim 25, the detecting circuit computes the coordinate in the first direction of the touch position by a formula, X=(V_{d1}−V_{c1})/(V_{c1}+V_{d1}), where Vc₁ s the voltage variation at the first end of the sensing line with the maximum voltage variation and V_{d1} is the voltage variation at the second end of the sensing line.

27. The touch panel of claim 25, wherein the detecting circuit computes the coordinate in the first direction of the touch position by a formula,
$$X = \frac{{\sum }_{i = 1}^{M} ( {V}_{di} - {V}_{ci} )}{{\sum }_{i = 1}^{M} ( {V}_{ci} + {V}_{di} )} ,$$
where M is the number of the sensing lines with the maximum voltage variation, V_{ci} is the voltage variation at the first end of the sensing line i (i=1, 2, 3 . . . M) and V_{di} is the voltage variation at the second end of the sensing line i.

28. The touch panel of claim 24, wherein the detecting circuit computes a coordinate in the second direction of the touch position in accordance with the center of gravity of the voltage variation of the sensing lines.

29. The touch panel of claim 28, wherein the detecting circuit computes the coordinate in the second direction of the touch position by a formula,
$$Y = \frac{{\sum }_{i = 1}^{N} {Y}_{i} \cdot {V}_{ci}}{{\sum }_{i = 1}^{N} {V}_{ci}} ,$$
where N is the number of the sensing lines of the sensing layer, Yᵢ is the coordinate in the second direction of the sensing line i (i=1, 2, 3 . . . N) and V_{ci} is the voltage variation at the first end of the sensing line i.

30. The touch panel of claim 28, wherein the detecting circuit computes the coordinate in the second direction of the touch position by a formula,
$$Y = \frac{{\sum }_{i = 1}^{N} {Y}_{i} \cdot {V}_{di}}{{\sum }_{i = 1}^{N} {V}_{di}} ,$$
where N is the number of the sensing lines of the sensing layer, Yᵢ is the coordinate in the second direction of the sensing line i (i=1, 2, 3 . . . N) and V_{di} is the voltage variation at the second end of the sensing line i.

31. The touch panel of claim 28, wherein the detecting circuit computes the coordinate in the second direction of the touch position by a formula,
$$Y = \frac{{\sum }_{i = 1}^{N} {Y}_{i} \cdot ( {V}_{ci} + {V}_{di} )}{{\sum }_{i = 1}^{N} ( {V}_{ci} + {V}_{di} )} ,$$
where N is the number of the sensing lines of the sensing layer, Yᵢ is the coordinate in the second direction of the sensing i line i (i=1, 2, 3 . . . N), V_{ci} is the voltage variation at the first end of the sensing line i and V_{di} is the voltage variation at the second end of the sensing line i.
